(19) United States
(12) Patent Application Publication
(10) Pub. No.: US 2012/0275094 A1
(43) Pub. Date: Nov. 1, 2012

(54) SUPPORTING MECHANISM AND ELECTRONIC DEVICE

(75) Inventors: CONG-BING ZHOU, Shenzhen City (CN); CHIA-TE YU, Tu-Cheng (TW); QUAN-CHANG CHENG, Shenzhen City (CN); LIN-LIN PAN, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/244,400

(22) Filed: Sep. 24, 2011

(30) Foreign Application Priority Data
Apr. 28, 2011 (CN) 201110108544.6

(51) Int. Cl. H05K 7/00

(52) U.S. Cl. 361/679.01

(57) ABSTRACT

A supporting mechanism for supporting an electronic device, the electronic device includes a first sidewall and at least one second sidewall. The supporting mechanism comprises a rotating tray and a supporting bracket. The rotating tray is rotatably coupled to the electronic device, and the supporting bracket is pivotably coupled to and foldable on the rotating tray. When the rotating tray is rotated with the supporting bracket perpendicular to the first sidewall, the supporting bracket is unfolded and cooperates with the first sidewall to support the electronic device in the first direction. When the rotating tray is rotated with the supporting bracket perpendicular to the at least one second sidewall, the supporting bracket is unfolded and cooperates with the at least one second sidewall to support the electronic device in a second direction different from the first direction. An electronic device is also provided.

### BACKGROUND

1. Technical Field

The present disclosure relates to electronic devices, and particularly to an electronic device using a supporting mechanism.

2. Description of Related Art

Hand-held electronic devices, such as PDAs, MP3s, and mobile phones, for example, are widely used in daily life. However, most of these hand-held electronic devices do not have a supporting mechanism. When the hand-held electronic devices are used to watch movies or read e-books, the users need to support or hold the device with their hands, this is an inconvenience.

Therefore, there is room for improvement in the art.

### BRIEF DESCRIPTION OF THE DRAWINGS

FIG. 1 is a perspective view of an electronic device having a supporting mechanism in accordance with an exemplary embodiment.

FIG. 2 is a perspective view of the housing of FIG. 1.

FIG. 3 is an perspective view of the rotating tray of FIG. 1.

FIG. 4 is an exploded view of the supporting bracket of FIG. 1.

FIG. 5 shows the electronic device of FIG. 1 in the first state.

FIG. 6 shows the electronic device of FIG. 1 in the second state.

### DETAILED DESCRIPTION

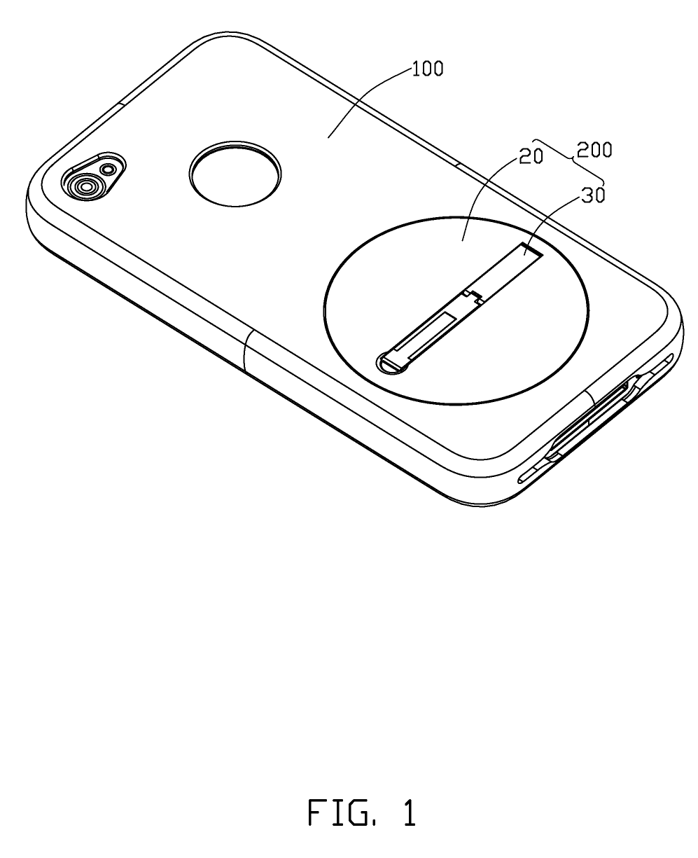

Referring to FIG. 1, an electronic device 100 having a supporting mechanism 200 in accordance with an embodiment is shown. The electronic device 100 may be a mobile-phone, a personal digital assistant (PDA), PSP and other hand-held electronic devices. The supporting mechanism 200 is rotatably coupled to the electronic device 100, and operatively supports the electronic device 100 in different positions such as landscape position and portrait position.

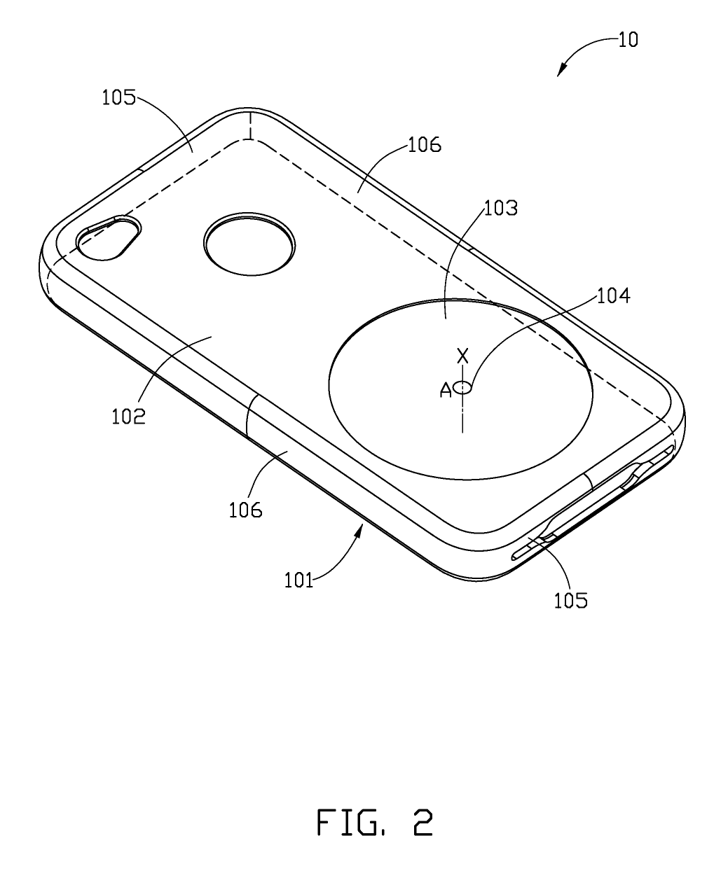

Referring to FIG. 2, the electronic device 100 is substantially rectangular, and includes a housing 10. The housing 10 is hollow and includes a front cover 101, a rear cover 102 engaging with the front cover 101, and four sidewalls (hereinafter, two opposite first sidewalls 105, two opposite second sidewalls 106) sandwiched between the front cover 101 and the rear cover 102. The four sidewalls serially interconnect and cooperate with the front cover 101 and the rear cover 102 to define a receiving space (not shown) for receiving processors, a power supply, and other components (not shown) for operating the electronic device 100. The outer surface of the rear cover 102 defines a receiving groove 103 for receiving the supporting mechanism 200. The receiving groove 103 is substantially circular and has a center A. The bottom of the receiving groove 103 defines a through hole 104 at the centre A. In another embodiment, the housing 10 may be a protection shell for accommodating and protecting an electronic device.

Referring again to FIG. 1, the supporting mechanism 200 includes a rotating tray 20 and a supporting bracket 30 mounted to the rotating tray 20. The rotating tray 20 is rotatably received in the housing 10 via the through hole 104. The length of the supporting bracket 30 is adjustable, such that the position of the electronic device 100 is adjustable.

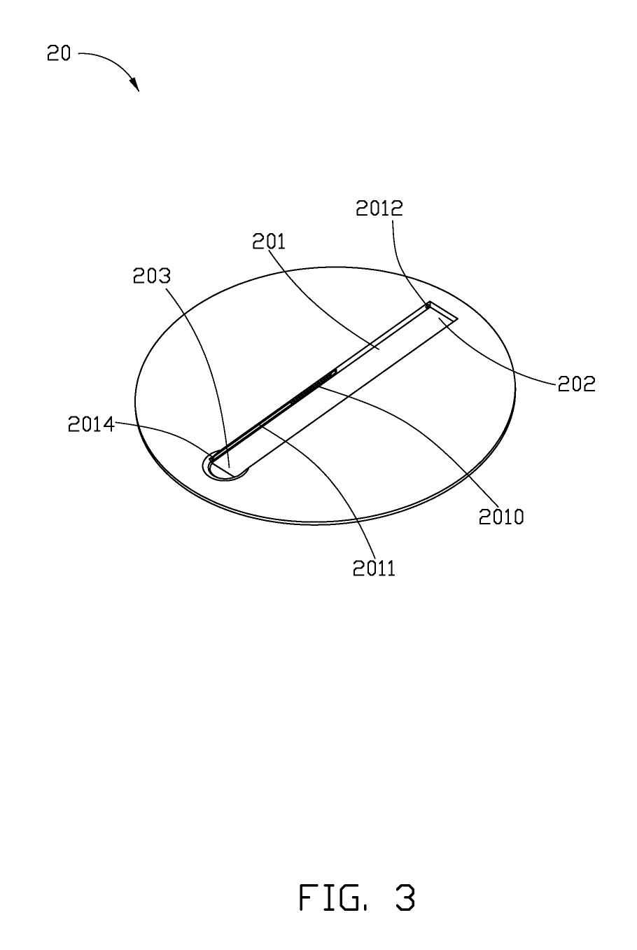

Referring to FIG. 3, the rotating tray 20 is substantially circular. The rotating tray 20 is rotatable around an axis X (see FIG. 2) perpendicular to the rear cover 102. The middle of the rotating tray 20 defines an elongated sliding slot 201 for receiving the supporting bracket 30. The sliding slot 201 includes a first end 202 and a second end 203 opposite to the first end 202. Two shaft holes 2012 are defined at opposite sides of the sliding slot 201 and are arranged adjacent to the first end 202. Two sliding rails 2011 are defined at opposite sides of the sliding slot 201. Each sliding rails 2011 further define a toothed portion 2010. Furthermore, a locking member 2014 is arranged at the second end 203 and allows the supporting bracket 30 to be latched to and unlatched from the rotating tray 20 when the supporting bracket 30 is received in the sliding slot 201.

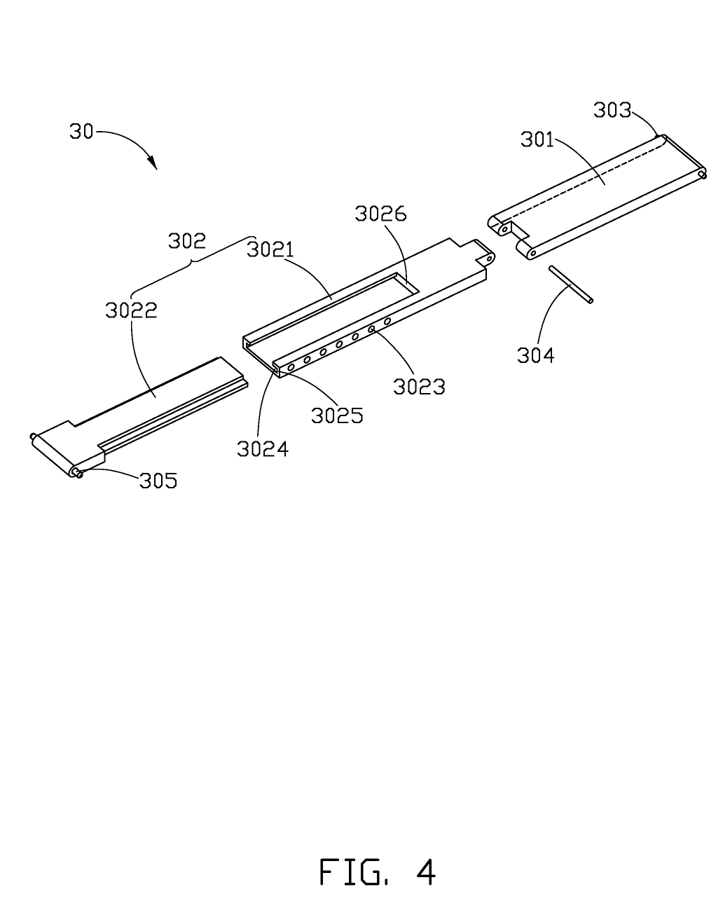

Referring to FIG. 4, the supporting bracket 30 includes a first arm 301 and a second arm 302 pivotally connected to the first arm 301. A pivoting rod 303 projects from an end of the first arm 301. The pivoting rod 303 is rotatably received in the shaft hole 2012, such that the first arm 301 is rotatably connected to the rotating tray 20. The second arm 302 is pivotally coupled to the other end of the first arm 301 opposite to the pivoting rod 303 via a shaft 304. The length of the second arm 302 is adjustable. The second arm 302 includes a positioning portion 3021 and an adjustable portion 3022 slidably received in the positioning portion 3021.

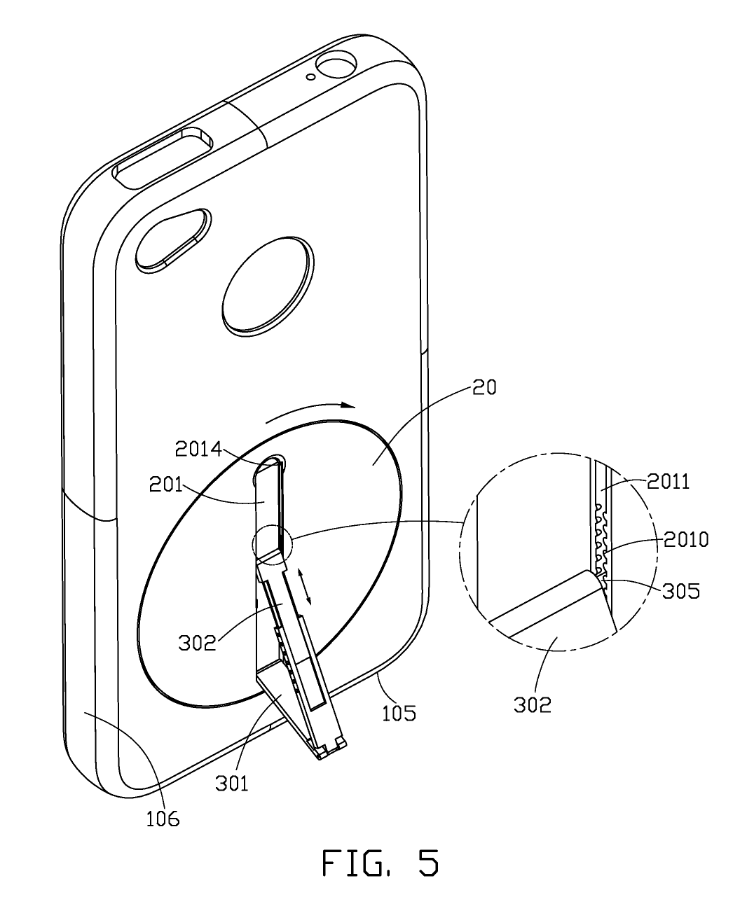

An end of the positioning portion 3021 opposite to the first arm 301 recesses longitudinally to define a receiving slot 3024 for receiving the adjustable portion 3022. The receiving slot 3024 has an opening 3025 for allowing the adjustable portion 3022 to be inserted. A side of the positioning portion 3021 evenly defines a plurality of positioning holes 3023 communicating with the receiving slot 3024. When the adjustable portion 3022 is received in the receiving slot 3024 with an end resisting against the end portion 3026, the second arm 302 telescopes and the length is decreased to minimum. When the adjustable portion 3022 slides along receiving slot 3024 in a direction of opposite to the end portion 3026, the adjustable portion 3022 is extended out of the receiving slot 3024, and the length of the second arm 302 is elongated. In this state, a positioning member (not shown) extends through the positioning holes 3023 to position the adjustable portion 3022 in a desirable position. Two protruding posts 305 protrude from an end of the second arm 302 opposite to the positioning portion 3021 and are parallel to the pivoting rod 303. The two protruding posts 305 are slidable along the sliding rail 2011 and are positioned in a desire position by the toothed portion 2010. The first arm 301 makes room for the second arm 302 when the second arm 302 is rotated at an angle with the first arm 301 (see FIG. 5).

When the second arm 302 telescopes, the total sum of the length of the first arm 301 and that of the second arm 302 is slightly less than the length of the sliding slot 201. Thus, both the first arm 301 and the second arm 302 can be received in the sliding slot 201 when they are not in a working state (referring to FIG. 1).

In assembly, the first arm 301 is fixed in the shaft hole 2012 of the rotating tray 20 via the pivoting rod 303. The second arm 302 is pivotally coupled to the first arm 301 via the shaft 304 with the protruding post 305 being slidably received in the sliding rail 2011, and the rotating tray 20 is rotatably coupled to the housing 10 via the through hole 104.

Referring to FIG. 5, to support the electronic device 100 in a first position: the rotating tray 20 is rotated with the supporting bracket 30 substantially parallel to the second sidewalls 106. The protruding post 305 is unlatched from locking member 2014 and is driven to slide along the sliding rail 2011 to be positioned in a desired position, and the first arm 301 is simultaneously drawn from the sliding slot 201. As a result, the first arm 301 angles with the second arm 302, and further cooperates with one of the first sidewalls 105 to support the electronic device 100 in the first position.

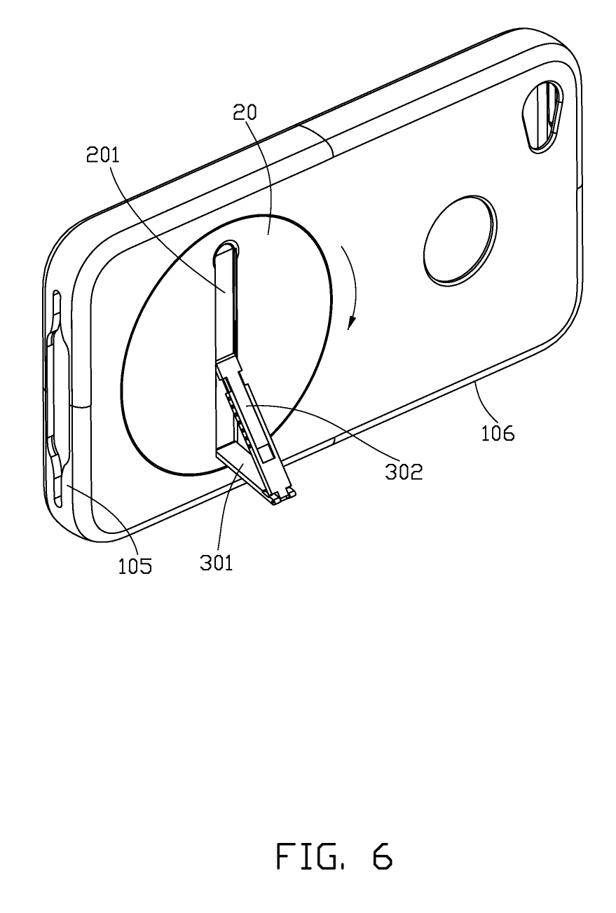

Referring to FIG. 6, to support the electronic device 100 in a second position different from the first position: the rotating tray 20 is rotated with the supporting bracket 30 to be substantially parallel to the first sidewalls 105 with the first arm 301 being drawn from the sliding slot 201 and angling with the second arm 302. As a result, the first arm 301 angles with the second arm 302, and further cooperates with one of the second sidewalls 106 to support the electronic device 100 in the second position.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A supporting mechanism for supporting an electronic device, the electronic device comprising a first sidewall and at least one second sidewall different from the first sidewall, the supporting mechanism comprising:
a rotating tray rotatably coupled to the electronic device; and
a supporting bracket pivotally coupled to and being foldable on the rotating tray;
wherein when the rotating tray is rotated with the supporting bracket perpendicular to the first sidewall, the supporting bracket is unfolded and cooperates with the first sidewall to support the electronic device in the first direction; when the rotating tray is rotated with the supporting bracket perpendicular to the at least one second sidewall, the supporting bracket is unfolded and cooperates with the at least one second sidewall to support the electronic device in a second direction different from the first direction.

2. The supporting mechanism as described in claim 1, wherein an elongated sliding slot is defined in the middle of the rotating tray for receiving the supporting bracket.

3. The supporting mechanism as described in claim 2, wherein the sliding slot comprises a first end and a second end opposite to the first end.

4. The supporting mechanism as described in claim 3, wherein two shaft holes are defined at opposite side of the sliding slot and are arranged adjacent to the first end.

5. The supporting mechanism as described in claim 2, wherein two sliding rails are defined at opposite sides of the sliding slot, each sliding rails further defines a toothed portion.

6. The supporting mechanism as described in claim 3, wherein a locking member is arranged at the second end and allows the supporting bracket being latching to and unlatching from the rotating tray when the supporting bracket is received in the sliding slot.

7. The supporting mechanism as described in claim 1, wherein the supporting bracket comprises a first arm and a second arm pivotally connected to the first arm.

8. The supporting mechanism as described in claim 7, wherein the second arm comprises a positioning portion and an adjustable portion slidably received in the positioning portion, the length of the second arm is adjustable.

9. The supporting mechanism as described in claim 8, wherein a receiving slot is defined in the one end of the positioning portion opposite to the first arm, and the receiving slot has an opening, and a plurality of positioning holes are defined in the side of the positioning portion.

10. The supporting mechanism as described in claim 9, wherein when the second arm telescopes, the total sum of the length of the first arm and the second arm is slightly less than the length of the sliding slot, thus, both the first arm and the second arm can be received in the sliding slot when they are not in a working state.

11. An electronic device comprising:
a body comprising a first sidewall and at least one second sidewall; and
a supporting mechanism for supporting the electronic device in a first orientation and in a second orientation different from the first orientation, wherein the supporting mechanism comprises:
a rotating tray rotatably coupled to the electronic device, and
a supporting bracket pivotally coupled to and being foldable on the rotating tray;
wherein when the rotating tray is rotated with the supporting bracket perpendicular to the first sidewall, the supporting bracket is unfolded and cooperates with the first sidewall to support the electronic device in the first direction; when the rotating tray is rotated with the supporting bracket perpendicular to the at least one second sidewall, the supporting bracket is unfolded and cooperates with the at least one second sidewall to support the electronic device in a second direction different from the first direction.

12. The electronic device as described in claim 11, wherein an elongated sliding slot is defined in the middle of the rotating tray for receiving the supporting bracket.

13. The electronic device as described in claim 12, wherein the sliding slot comprises a first end and a second end opposite to the first end.

14. The electronic device as described in claim 13, wherein two shaft holes are defined at opposite side of the sliding slot and are arranged adjacent to the first end.

15. The electronic device as described in claim 12, wherein two sliding rails are defined at opposite sides of the sliding slot, each sliding rails further defines a toothed portion.

16. The electronic device as described in claim 13, wherein a locking member is arranged at the second end and allows the supporting bracket being latching to and unlatching from the rotating tray when the supporting bracket is received in the sliding slot.

17. The electronic device as described in claim 11, wherein the supporting bracket comprises a first arm and a second arm pivotally connected to the first arm.

18. The electronic device as described in claim 17, wherein the second arm comprises a positioning portion and an adjustable portion slidably received in the positioning portion, the length of the second arm is adjustable.

19. The electronic device as described in claim 18, wherein a receiving slot is defined in the one end of the positioning portion opposite to the first arm, and the receiving slot has an opening, and a plurality of positioning holes are defined in the side of the positioning portion.

20. The electronic device as described in claim 19, wherein when the second arm telescopes, the total sum of the length of the first arm and the second arm is slightly less than the length of the sliding slot, thus, both the first arm and the second arm can be received in the sliding slot when they are not in a working state.
